(19) United States
(12) Patent Application Publication
(10) Pub. No.: US 2008/0138176 A1
(43) Pub. Date: Jun. 12, 2008

(54) Apparatus for manufacturing semiconductor device

(75) Inventors: Hyung-Joon Kim, Gyeonggi-do (KR); Seung-Bae Lee, Gyeonggi-do (KR); Dae-Hyun Yang, Gyeonggi-do (KR); Ki-Yung Lee, Jeollanam-do (KR)

Correspondence Address: Grant J. Scott;Myers Bigel Sibley & Sajovee, P.A., P. O. Box 37428, Raleigh, NC, 27627, US

(73) Assignee: Semes Co., Ltd.

(21) Appl. No.: 11/881,012

(22) Filed: Jul. 25, 2007

(30) Foreign Application Priority Data
Dec. 12, 2006 (KR) 10-2006-0126363

(51) Int. Cl. H01L 21/677

(52) U.S. Cl. 414/217; 901/6

(57) ABSTRACT

The present invention provides an apparatus for manufacturing a semiconductor device. The apparatus includes vacuum wafer transfer modules disposed in a line so as to correspond to stages, a loadlock chamber module transferring wafers in vacuum, first process chambers disposed around the vacuum wafer transfer modules so as to process the wafers transferred from the loadlock chamber module, first buffer stages disposed in the vacuum wafer transfer modules so that the wafers are loaded thereon and unloaded therefrom, a first transfer robot disposed between the first process chambers so as to transfer the wafers from the loadlock chamber module to the first process chambers and then to transfer the wafers from the loadlock chamber module onto the first buffer stages, second process chambers disposed around the vacuum wafer transfer modules so as to process the wafers transferred from the first buffer stages, and a second transfer robot disposed between the second process chambers so as to transfer the wafers, which are transferred to the first buffer stages, to the second process chambers.

### CROSS REFERENCE TO RELATED APPLICATION

This application claims priority from Korean Patent Application No. 10-2006-0126363 filed on Dec. 12, 2006 in the Korean Intellectual Property Office, the disclosure of which is incorporated herein by reference in its entirety.

### BACKGROUND OF THE INVENTION

1. Field of the Invention

The present invention relates to an apparatus for manufacturing a semiconductor device, and more particularly, to an apparatus for manufacturing a semiconductor device that improves reliability and processing speed in a process of processing a semiconductor device.

2. Description of the Related Art

A process of processing a semiconductor device is a process where depositing an insulating film and metal material, etching the insulating film and metal material, and applying a photosensitizer, developing the photosensitizer, ashing, and cleaning are repeated several times so as to form a fine patterning arrangement.

Apparatuses used to perform the process are classified into a batch processor and a single processor in consideration of the number of processed substrates.

A batch processor has an advantage of processing many substrates (for example, twenty-five or fifty substrates) in process chambers at one time. However, according to the batch processor, as a diameter of the substrate has been increased, the size of the process chamber has been increased. For this reason, there are problems in that the size of the apparatus and fluid usage is increased and it is not possible to process a plurality of substrates under a constant condition.

Accordingly, as a diameter of the substrate has increased in recent years, a single processor has come into the spotlight. The single processor has the following advantage. That is, since a substrate is processed in the process chamber of the single processor, it is possible to process substrates under a constant condition.

FIG. 1 shows a single processor type vacuum chamber system in the related art.

A single processor type vacuum chamber system 1 in the related art includes a load module 2, an atmosphere transfer module (ATM TM) 4, a loadlock (L/L) chamber module 6, a vacuum wafer transfer module 10, and process chambers 12.

The load module 2 is used to load and unload wafers, and the wafers are generally received in wafer cassettes and then loaded or unloaded.

The wafers transferred from the load module 2 are transferred through the atmosphere transfer module 4. In this case, the wafers are transferred by a robot arm.

The wafers passing through the atmosphere transfer module 4 are loaded into loadlock chambers 8 of the loadlock chamber module 6. In this case, notches of the wafers are aligned by an aligner (not shown), and the wafers are then loaded into the loadlock chambers 8.

In the next process, after pumping is performed on the wafers in the loadlock chambers 8, the wafers pass through the vacuum wafer transfer module 10 and are then loaded into the process chambers 12.

Further, when the wafers are loaded into the process chambers 12, a process of processing a wafer is performed. When the process of processing a wafer is completed, the wafers are unloaded in accordance with a reverse procedure of the loading procedure.

However, since the process chambers 12 are disposed around the vacuum wafer transfer module 10 as described above, the single processor type vacuum chamber system 1 in the related art has a large foot print 14 and the number of process chambers 12 that can be used in the system is limited. Further, the single processor type vacuum chamber system has a problem in that the number of manufactured wafers is limited by the processing speed of the vacuum wafer transfer module 10.

### SUMMARY OF THE INVENTION

An object of the present invention is to provide an apparatus for manufacturing a semiconductor device to improve reliability and processing speed in a process of processing a semiconductor device.

Objects of the present invention are not limited to those mentioned above, and other objects of the present invention will be apparently understood by those skilled in the art through the following description.

According to an aspect of the present invention, there is provided an apparatus for manufacturing a semiconductor device, the apparatus including vacuum wafer transfer modules disposed in a line so as to correspond to stages, a loadlock chamber module transferring wafers in vacuum, first process chambers disposed around the vacuum wafer transfer modules so as to process the wafers transferred from the loadlock chamber module, first buffer stages disposed in the vacuum wafer transfer modules so that the wafers are loaded thereon and unloaded therefrom, a first transfer robot disposed between the first process chambers so as to transfer the wafers from the loadlock chamber module to the first process chambers and so as to transfer the wafers from the loadlock chamber module onto the first buffer stages, second process chambers disposed around the vacuum wafer transfer modules so as to process the wafers transferred from the first buffer stages, and a second transfer robot disposed between the second process chambers so as to transfer the wafers, which are transferred to the first buffer stages, to the second process chambers.

### BRIEF DESCRIPTION OF THE DRAWINGS

The above and other features and advantages of the present invention will become more apparent by describing in detail preferred embodiments thereof with reference to the attached drawings in which:

FIG. 1 is a view showing a single processor type vacuum chamber system in the related art;

FIG. 2 is a view showing an apparatus for manufacturing a semiconductor device according to an embodiment of the present invention; and

FIG. 3 is a view showing an apparatus for manufacturing a semiconductor device according to another embodiment of the present invention.

### DESCRIPTION OF THE PREFERRED EMBODIMENTS

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

It will be understood that when an element or a layer is referred to as being “on” another element or layer, it can be directly on the other element or intervening elements may also be present. In contrast, when an element is referred to as being “directly on” another element, there are no intervening elements present. Like reference numerals refer to like elements throughout the specification.

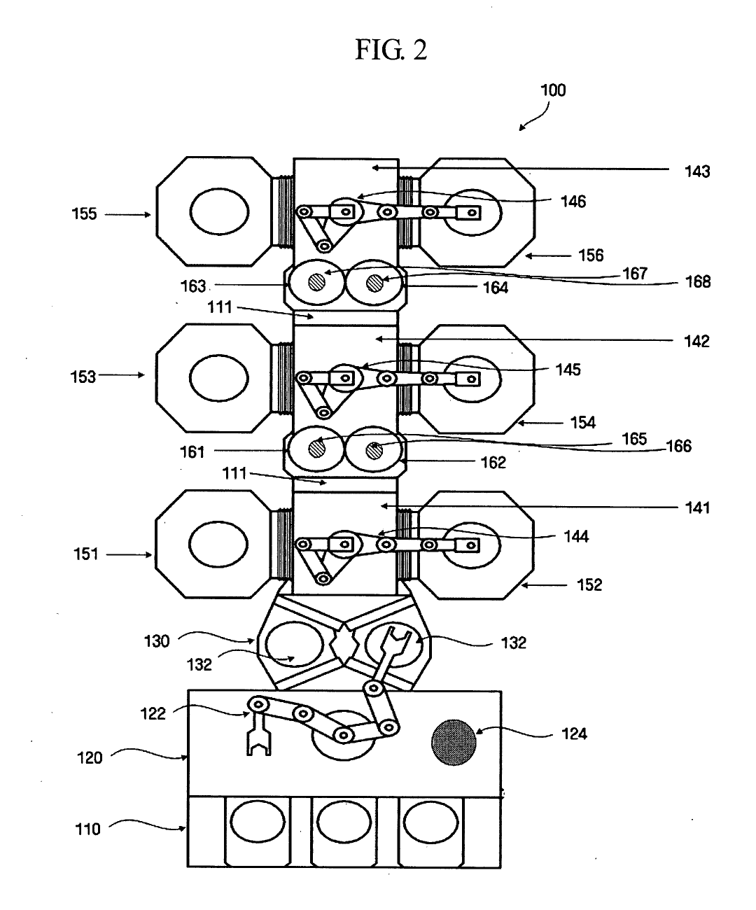

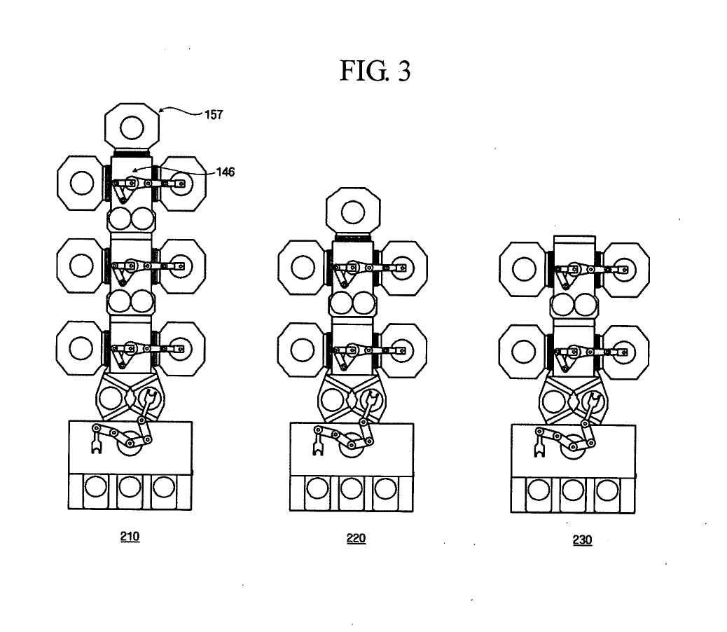

FIG. 2 is a view showing an apparatus for manufacturing a semiconductor device according to an embodiment of the present invention. FIG. 3 is a view showing an apparatus for manufacturing a semiconductor device according to another embodiment of the present invention.

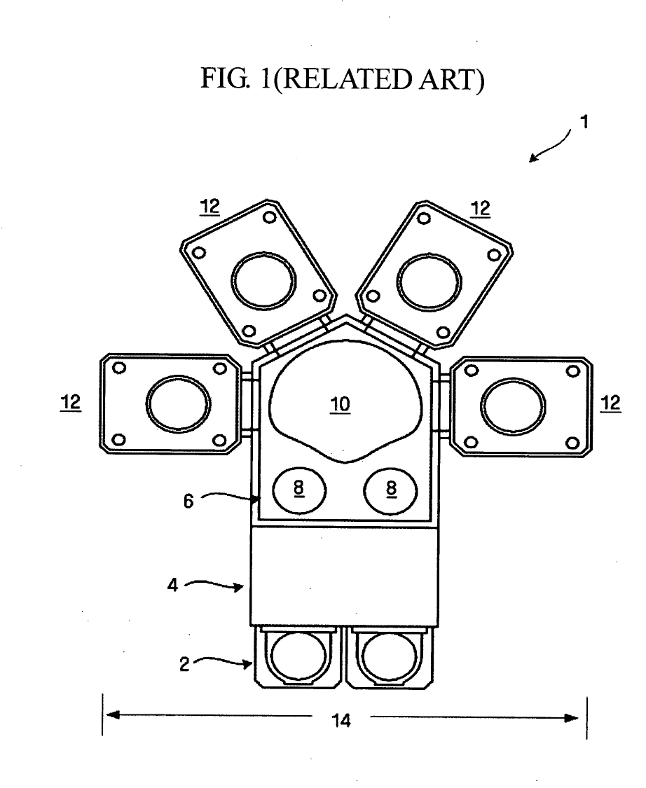

As shown in FIG. 2, an apparatus 100 for manufacturing a semiconductor device includes a load module 110, an atmosphere transfer module 120, a loadlock chamber module 130, vacuum wafer transfer modules 141 to 143, process chambers 151 to 156, and buffer stages 161 to 164. As shown in FIG. 1, according to the related art, a plurality of process chambers 12 is disposed around one vacuum wafer transfer module 10. However, according to the present invention, the vacuum wafer transfer modules 141 to 143 are disposed at stages, respectively, and are aligned in a line so as to correspond to a reference axis. Further, transfer robots 144 to 146 are disposed in the vacuum wafer transfer modules 141 to 143, respectively. In addition, the buffer stages 161 to 164 where wafers are loaded and unloaded are provided. The process chambers 151 to 156 are disposed on both sides of the stages so as to face each other. The number of the process chambers 151 to 156 may be changed as shown in FIG. 3. In this case, if odd number process chambers are provided, the process chambers may be disposed at predetermined positions around the vacuum wafer transfer modules 141 to 143. Hereinafter, each of the components will be described in more detail.

The load module 110 is used to load and unload wafers, and wafers are generally received in wafer cassettes and then loaded or unloaded. When wafers are transferred or stored during the process of manufacturing a semiconductor device, the wafer cassettes are used to prevent the wafers from being contaminated. Each of the wafer cassettes is provided with a plurality of slots in which wafers are horizontally received. The wafers are received in the slots. In this case, for example, twenty-five wafers may be received in the slots. The wafers transferred from the load module 110 are transferred through the atmosphere transfer module 120.

The atmosphere transfer module 120 provides transfer paths of wafers between the load module and the loadlock chamber module. Further, the atmosphere transfer module 120 includes a wafer transfer robot 122 and a prealigner 124. The wafer transfer robot 122 takes out wafers from the wafer cassette loaded in the load module 110, and transfers the wafers to loadlock chambers 132 of the loadlock chamber module 130. The wafer transfer robot 122 can be moved up and down so as to take out wafers from the slots of the wafer cassette and so as to insert the wafers into the slots of the loadlock chamber 132. The prealigner 124 positions the wafers, and determines the directions of the notches of the wafers.

The loadlock chamber module 130 is used to transfer the wafers in a vacuum. Before the wafers are transferred to the process chamber, where the process of manufacturing a semiconductor device is performed, the loadlock chamber 132 of the loadlock chamber module 130 allows the wafers to be in an atmosphere similar to a condition of the process chamber. Further, the loadlock chamber 132 allows the atmosphere in the process chamber to be affected by external conditions. In addition, the loadlock chamber 132 may be in the atmospheric state so as to correspond to the processing procedure, or may be in a vacuum. The loadlock chamber 132 is provided with wafer cassettes, which includes a plurality of slots corresponding to the number of the process chambers.

Wafers loaded into the loadlock chamber 132 are transferred to the left and right first process chambers 151 and 152 by the first transfer robot 144 of the first wafer transfer module 141. That is, the first transfer robot 144 provides transfer paths of wafers between the loadlock chamber module 130 and the first process chambers 151 and 152.

Further, wafers left in the loadlock chamber 132 are transferred onto the first buffer stages 161 and 162 by the first transfer robot 144.

The vacuum wafer transfer modules 141 to 143 include the transfer robots 144 to 146 and the buffer stages 161 to 164. The vacuum wafer transfer modules 141 to 143 are disposed at stages, respectively, and are aligned in a line. In addition, the vacuum wafer transfer modules 141 to 143 are connected with each other through vacuum valves 111. The transfer robots 144 to 146 are provided in the vacuum wafer transfer modules 141 to 143, respectively, to transfer wafers. Further, the buffer stages 161 to 164 are not provided on the front side of the vacuum wafer transfer module 141, but are provided on the front sides of the vacuum wafer transfer modules 142 and 143. The reason for this is that the wafers loaded into the loadlock chamber 132 by the first transfer robot 144 are transferred to the left and right first process chambers 151 and 152 by the first transfer robot 144 on the front side of the vacuum wafer transfer module 141. Each of the vacuum wafer transfer modules 141 to 143 includes a controller (not shown). When operational errors occur in any one of the transfer robots 144 to 146, the controller drives the rest of the transfer modules 141 to 143. For example, when the third transfer robot 143 is stopped due to the failure thereof, the controller detects the failure and performs the process of manufacturing a semiconductor device by the transfer robots 141 and 142. The controller is mounted in each of the vacuum wafer transfer modules 141 to 143, or is mounted at a predetermined portion in the apparatus for manufacturing a semiconductor device. Accordingly, the controllers can centralize the detection and control of operational errors of devices in the vacuum wafer transfer modules 141 to 143.

The transfer robots 144 to 146 are provided in the vacuum wafer transfer modules 141 to 143, respectively, and are disposed to correspond to the stages. The transfer robots 144 to 146 perform a take-in operation of taking wafers into the process chambers 151 to 156, and a take-out operation of taking the processed wafers from the process chambers 151 to 156. Further, the transfer robots 144 to 146 transfer wafers between the buffer stages 161 to 164 and the process chambers 151 to 156.

In more detail, the first transfer robot 144 transfers the wafers loaded into the loadlock chamber 132 to the left and right first process chambers 151 and 152. In addition, the first transfer robot 144 transfers the wafers left in the loadlock chamber 132 to the first buffer stages 161 and 162. In this case, any one of the first buffer stages 161 and 162 may be exclusively used for loading and unloading the wafers.

Further, the second transfer robot 145 transfers the wafers loaded into the first buffer stages 161 and 162 to the left and right second process chambers 153 and 154, and transfers the wafers left in the first buffer stages 161 and 162 to the second buffer stages 163 and 164.

Furthermore, the third transfer robot 146 transfers the wafers loaded into the second buffer stages 163 and 164 to the left and right third process chambers 155 and 156. The transfer robots 144 to 146 may have the structure of a dual arm or dual end effector in order to minimize a load factor.

The buffer stages 161 to 164 are provided in the second and third vacuum wafer transfer modules 142 and 143, and are used to load and unload the wafers. Each of the buffer stages 161 to 164 is provided with a plurality of slots. For example, the wafers left in the loadlock chamber 132 are transferred onto the first buffer stages 161 and 162 by the first transfer robot 144, and then inserted into the slots of the first buffer stages 161 and 162. Further, as described above, the buffer stages 161 to 164 are not provided on the front side of the vacuum wafer transfer module 141, and are provided on the front sides of the vacuum wafer transfer modules 142 and 143.

In addition, the buffer stages 161 to 164 may be composed of wafer loading buffer stages or wafer unloading buffer stages. For example, one of the first buffer stages 161 and 162 may be used as a wafer loading buffer stage, and the other first buffer stage may be used as a wafer unloading buffer stage.

In this case, wafers are transferred onto the buffer stage used as a wafer loading buffer stage, and a semi aligner to be described below is mounted on the buffer stage used as a wafer loading buffer stage. Accordingly, the prealigner 124 can position the wafer and determine the directions of the notches of the wafers. Further, the processed wafers are unloaded from the buffer stage used as a wafer unloading buffer stage, and a separate semi aligner may not be mounted on the buffer stage used as a wafer unloading buffer stage. The interval between the slots of the buffer stages 161 to 164 may be larger than the thickness of the wafer so as to prevent the wafers from being damaged when wafers are inserted into the slots of the buffer stages 161 to 164.

The buffer stages 161 to 164 are provided in the vacuum wafer transfer modules 141 to 143, respectively, as described above, so that it is possible to efficiently use the apparatus for manufacturing a semiconductor device and to improve the efficiency of the manufacturing process.

Semi aligners 165 to 168 position the wafers and determine the direction of the notches of the wafers. For example, when one of the first buffer stages 161 and 162 is used as a wafer loading buffer stage used for loading wafers, the semi aligners 165 to 168 may be mounted on the corresponding buffer stages. In contrast, when the other first buffer stage is used as a wafer unloading buffer stage used for unloading wafers, the semi aligners may not be mounted on the corresponding buffer stages.

The directions of the notches of the wafers are basically determined by the prealigner 124. For example, when the direction of the notch corresponds to a 3 o'clock direction, an angle between each of the wafers placed on the first semi aligners 165 and 166 and a wafer corresponding to the initial state is 135°. For this reason, the semi aligners 165 to 168 should rotate the wafers by the angle therebetween in order to transfer the wafers to the second process chambers 153 and 154 in a 3 o'clock direction.

The process chambers 151 to 156 are provided on both sides of the vacuum wafer transfer modules 141 to 143 so as to face each other. The process chambers 151 to 156 are spaces where the process of manufacturing a semiconductor device is performed. The wafers are transferred from the buffer stages 161 to 164 to the process chambers 151 to 156 through the vacuum wafer transfer modules 141 to 143. Further, diffusion, etching, and cleaning are performed on the wafers in the process chambers 151 to 156.

Meanwhile, the process chambers 151 to 156 may be formed to perform various wafer processing operations. For example, the process chambers 151 to 156 may be composed of CVD chambers in which an insulating film is deposited, etch chambers in which apertures or openings are formed in the insulating film by etching to form interconnection structure, PVD chambers in which barrier layers are deposited, PVD chambers in which a metal film is deposited, and the like, in various ways. Hereinafter, the wafers, which undergo the process of manufacturing a semiconductor device in the process chambers 151 to 156, are transferred to the buffer stages 161 to 164.

The above-mentioned apparatus for manufacturing a semiconductor device according to the embodiment shown in FIG. 2 may be formed in various ways as shown in FIG. 3.

FIG. 3 shows an apparatus for manufacturing a semiconductor device according to another embodiment of the present invention.

The above-mentioned apparatus for manufacturing a semiconductor device shown in FIG. 2 may be modified in various ways as shown in FIG. 3. For example, a first apparatus 210 for manufacturing a semiconductor device shown in FIG. 3 is an example when the number of the process chambers shown in FIG. 2 changes from 6 to 7. Accordingly, the third transfer robot 146 inserts wafers into an additional process chamber 157.

Further, second and third apparatuses 220 and 230 for manufacturing a semiconductor device are examples when the number of the process chambers shown in FIG. 2 is changed into 5 and 4 and the numbers of transfer robots, buffer stages, and semi aligners are decreased. The description of each device for the process of manufacturing a semiconductor device is referred to the description of FIG. 2.

Although the present invention has been described in connection with the exemplary embodiments of the present invention, it will be apparent to those skilled in the art that various modifications and changes may be made thereto without departing from the scope and spirit of the invention. Therefore, it should be understood that the above embodiments are not limitative, but illustrative in all aspects.

The above-mentioned apparatus for manufacturing a semiconductor device has the following advantages.

First, it is possible to obtain advantages of improving reliability and productivity in processing wafers.

Second, it is possible to obtain advantages of decreasing a foot print of an apparatus for manufacturing a semiconductor device and changing the number of process chambers for processing wafers so as to correspond to a process of manufacturing a semiconductor device.

What is claimed is:

1. An apparatus for manufacturing a semiconductor device, the apparatus comprising:
vacuum wafer transfer modules disposed in a line so as to correspond to stages;
a loadlock chamber module transferring wafers in vacuum;
first process chambers disposed around the vacuum wafer transfer modules so as to process the wafers transferred from the loadlock chamber module;
first buffer stages disposed in the vacuum wafer transfer modules so that the wafers are loaded thereon and unloaded therefrom;
a first transfer robot disposed between the first process chambers so as to transfer the wafers from the loadlock chamber module to the first process chambers and then to transfer the wafers from the loadlock chamber module onto the first buffer stages;
second process chambers disposed around the vacuum wafer transfer modules so as to process the wafers transferred from the first buffer stages; and
a second transfer robot disposed between the second process chambers so as to transfer the wafers, which are transferred to the first buffer stages, to the second process chambers.

2. The apparatus of claim 1, wherein the first buffer stages comprise semi aligners that position the wafers and determine the directions of notches of the wafers.

3. The apparatus of claim 2, wherein the semi aligners are mounted on portions of the first buffer stages where the wafers are loaded.

4. The apparatus of claim 2, wherein each of the first buffer stages comprises a plurality of slots where the wafers are inserted.

5. The apparatus of claim 1, further comprising:
controllers driving the rest of the first and second transfer robots, when operational errors occur in any one of the first and second transfer robots.

6. The apparatus of claim 1, further comprising:
second buffer stages receiving the wafers from the vacuum wafer transfer modules in which the first buffer stages are disposed.

7. The apparatus of claim 6, further comprising:
third process chambers processing the wafers transferred from the second buffer stages.

8. The apparatus of claim 1, further comprising:
a load module loading and unloading the wafers to be transferred to the loadlock chamber module; and
an atmosphere transfer module disposed between the load module and the loadlock chamber module so as to provide transfer paths of the wafers.
